(19) United States
(12) Patent Application Publication
(10) Pub. No.: US 2011/0001197 A1
(43) Pub. Date: Jan. 6, 2011

(54) METHOD FOR MANUFACTURING SEMICONDUCTOR DEVICE AND SEMICONDUCTOR DEVICE

(75) Inventors: Noriaki Fukiage, Amagasaki-shi (JP); Yoshihiro Kato, Yamanashi (JP); Tsunetoshi Arikado, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TOKYO ELECTRON LIMITED, MINATO-KU (JP)

(21) Appl. No.: 12/446,307

(22) PCT Filed: Oct. 10, 2007
(86) PCT No.: PCT/JP2007/069716

§ 371 Date: Apr. 20, 2009

(30) Foreign Application Priority Data
Oct. 19, 2006 (JP) 2006-285559
Sep. 13, 2007 (JP) 2007-238148

(51) Int. Cl. H01L 29/78; H01L 21/265

(52) U.S. Cl. 257/408; 438/527; 257/E21.334; 257/E29.266

(57) ABSTRACT

A sidewall spacer film or the like is removed without damaging a device structure section. Specifically disclosed is a method for manufacturing a semiconductor device, which comprises a step of forming a first thin film composed of GeCOH or GeCH on a substrate (21) to be processed, a step of removing a part of the first thin film and obtaining a remaining portion (30), and a processing step of performing a certain process on the substrate (21) through the space formed by removing the first thin film.

### DESCRIPTION OF THE RELATED ART

The present invention claims priority of Japanese Patent Application No. 2006-285559 filed on Oct. 19, 2006, and Japanese Patent Application No. 2007-238148 filed on Sep. 13, 2007, the contents of which are incorporated herein by reference.

### FIELD OF THE INVENTION

The present invention relates to a semiconductor device manufacturing method including a step for selectively processing a substrate to be processed through an opening of a mask thin film and the semiconductor device manufactured by the corresponding manufacturing method.

### BACKGROUND OF THE INVENTION

FIG. 5 shows a cross section of a conventional typical MOS transistor. Recently, there arises a demand for a technique capable of easily removing a film referred to as a sidewall spacer film 105 formed on a sidewall of a gate electrode 104. Hereinafter, technical background thereof will be explained.

In order to suppress a short channel effect, a region referred to as an extension 103 is formed between a source 101 and a drain 102 of a MOS transistor, the extension 103 having a shallow depth and a low concentration of dopants compared to the source 101 and the drain 102. The source 101, the drain 102 and the extension 103 have different concentrations of dopants and pn junction depths.

In a conventional semiconductor device manufacturing method, after a gate electrode 104 is formed, the extension 103 is formed and, then, the source 101 and the drain 102 having large depths are formed. After ion implantation is performed to form the source 101 and the drain 102, heat treatment for activating the implanted ions is carried out at a high temperature (about 1000° C.).

However, the conventional manufacturing method is disadvantageous in that impurities in the region of the extension 103 are diffused at a depth deeper than a design value because the extension 103 is thermally treated at the high temperature during formation of the regions of the source 101 and the drain 102.

To that end, there is suggested a method including the steps of forming the regions of the source 101 and the drain 102, removing the sidewall spacer film 105 (sidewall spacer) used as a mask and forming the extension 103. By forming the regions of the source 101 and the drain 102 before forming the region of the extension 103, the junction depth thereof can be controlled to a design value without exposing the region of the extension 103 to a high temperature.

In that case, the sidewall spacer film 105 used as a mask during formation of the regions of the source 101 and the drain 102 requires to be removed completely without damaging a base serving as the region of the extension 103. When a dry etching method is used to remove a silicon nitride film used as the sidewall spacer film 105, the base may be damaged. On the contrary, when a wet etching method is used, residues are generated depending on conditions.

The above drawbacks are not limited to the above example, but may also occur in the following process.

Conventionally, when a device is scaled down, it is expected to obtain improvement in performance. For example, when a MOS transistor is scaled down in accordance with a scaling rule, a drain current of the transistor increases. The increase of the drain current causes an increase of a signal transmission speed, and further leads to a high-speed memory device or MPU.

However, if a pattern size is scaled down to tens of nanometers, the performance of the transistor is not improved as much as expected even when the patterned size is reduced. For that reason, a strained silicon technique for improving carrier mobility is recently gaining attention.

A drain current is simply expressed by the following Eq.

Id=W/L·μ·Cox·[(Vg−Vt)·Vd−½·Vd²] Eq(1),

where, Id indicates a drain current; W and L represent a channel width and a channel length, respectively; Vg indicates a voltage applied to a gate (gate voltage); Vt represents a threshold voltage (voltage at which a transistor turns on); μ indicates mobility of a carrier such as an electron or a hole; and Cox represents a capacitance of a gate insulating film.

The technique for improving the mobility by straining silicon of a channel region has a purpose of increasing the drain current Id by increasing μ in Eq. (1).

As for a method for straining silicon, two methods have been reported. Hereinafter, a method for applying stress to a channel portion by depositing a silicon nitride film having high stress will be described with reference to drawings in connection with the present invention.

Referring to FIG. 5, a silicon nitride film 106 having high stress is formed at an uppermost portion. To be more specific, tensile stress is applied to the channel portion by depositing a silicon nitride film having a high tensile force on an n-type transistor, and compressive stress is applied to the channel portion by depositing a silicon nitride film having high compressive stress on a p-type transistor. As a result, mobility of electrons increases in the n-type transistor, and mobility of holes increases in the p-type transistor.

However, as can be clearly seen from FIG. 5, the sidewall spacer film 105 used for forming the source 101 and the drain 102 remains on both sides of the gate electrode 104, so that the stress is applied to the channel region. Accordingly, the stress of the silicon nitride film is not sufficiently applied to the channel region. In order to sufficiently apply the stress, it is preferable to remove the sidewall spacer film 105 and deposit a silicon nitride film directly on a gate.

Since a silicon nitride film (film deposited by thermal CVD or plasma CVD) is used as the sidewall spacer film 105, hot phosphoric acid is generally used to remove the silicon nitride film. However, even if hot phosphoric acid is used, an etching rate of the silicon nitride film is low and, hence, it is not possible to avoid an increase of etching time. Further, while the etching is performed for a long period of time, a metal silicide 107 is etched and becomes thin. As a consequence, a resistance of the gate electrode 104 or a diffusion layer increases.

Patent Document 1: Japanese Patent Laid-open Publication No. 2005-175132

### SUMMARY OF THE INVENTION

The object of the present invention is to provide a semiconductor device manufacturing method capable of manufacturing a semiconductor device having high integration and high performance by removing a sidewall spacer film and the like without damaging a device structure section.

In accordance with one aspect of the invention, there is provided a method for manufacturing a semiconductor device including: a step of forming a first thin film composed of GeCOH or GeCH on a substrate to be processed; a step of removing a portion of the first thin film to obtain the remaining portion; and a processing step of performing a process on the substrate through a space from which the first thin film is removed.

Preferably, the processing step includes a step of implanting ions of an element into the substrate through the space formed by removing the portion.

It is preferred that the method for manufacturing the semiconductor device further includes a step of removing the remaining portion and a step of implanting ions of an element into the substrate through a space formed by removing the remaining portion.

It is preferred that the method for manufacturing the semiconductor device further includes a step of depositing a second thin film on the substrate disposed below the space formed by removing the portion of the first thin film, wherein the processing step includes a step of forming a third thin film by chemically reacting the substrate and the second thin film in the space.

Preferably, the remaining portion and the second thin film are removed while leaving the third thin film.

Further, the step of removing the remaining portion may be performed by using a wet etching method.

Preferably, the wet etching method is carried out by using etching solution containing H2SO4 and H2O2.

Further, the processing step may include a step of removing a part of the substrate by using the space from which the first thin film is removed.

It is preferred that the substrate includes an interlayer dielectric, and the step of removing a part of the substrate includes a step of removing a part of the interlayer dielectric of the substrate.

In accordance with another aspect of the invention, there is provided a semiconductor device manufactured by a manufacturing method including a step of forming a first thin film composed of GeCOH or GeCH on a substrate to be processed; a step of removing a portion of the first thin film to obtain the remaining portion; and a processing step of performing a certain process on the substrate through a space formed by removing the portion of the first thin film.

### EFFECTS OF THE INVENTION

Since GeCOH or GeCH that can be easily removed by wet etching is used for a mask film (first thin film), the mask that became unnecessary can be removed without damaging a device structure section and, further, a semiconductor device having high integration and high performance can be manufactured.

### BRIEF DESCRIPTION OF THE DRAWINGS

FIGS. 1A to 1D explain processes of a first embodiment of the present invention;

FIGS. 2A to 2C explain processes of the first embodiment of the present invention;

FIGS. 3A to 3F explain processes of a second embodiment of the present invention;

FIGS. 4A to 4D explains processes of a third embodiment of the present invention; and

FIG. 5 shows a cross sectional view of a semiconductor device for explaining a conventional process.

### DETAILED DESCRIPTION OF THE EMBODIMENT

The embodiments of the present invention will be described with reference to the accompanying drawings which form a part hereof.

### First Embodiment

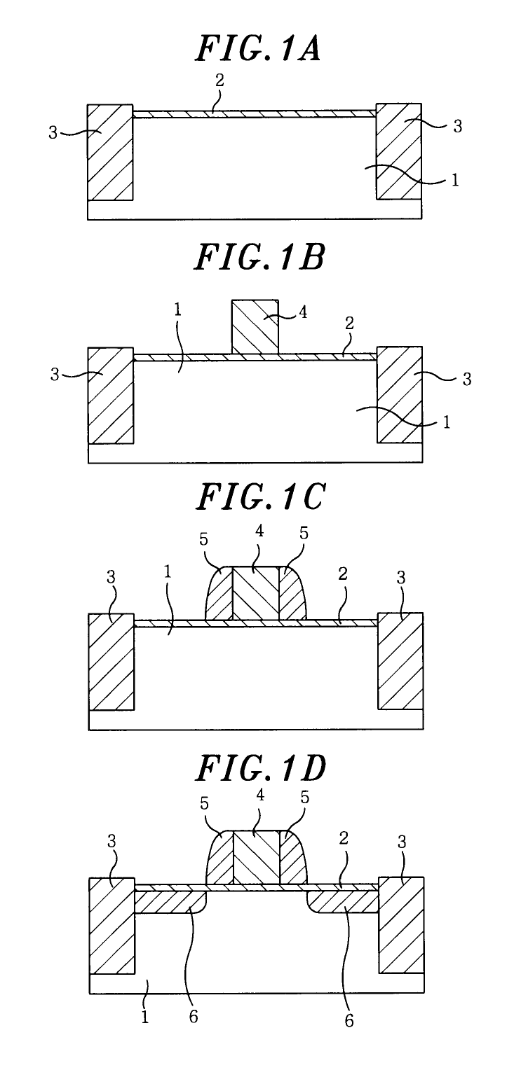

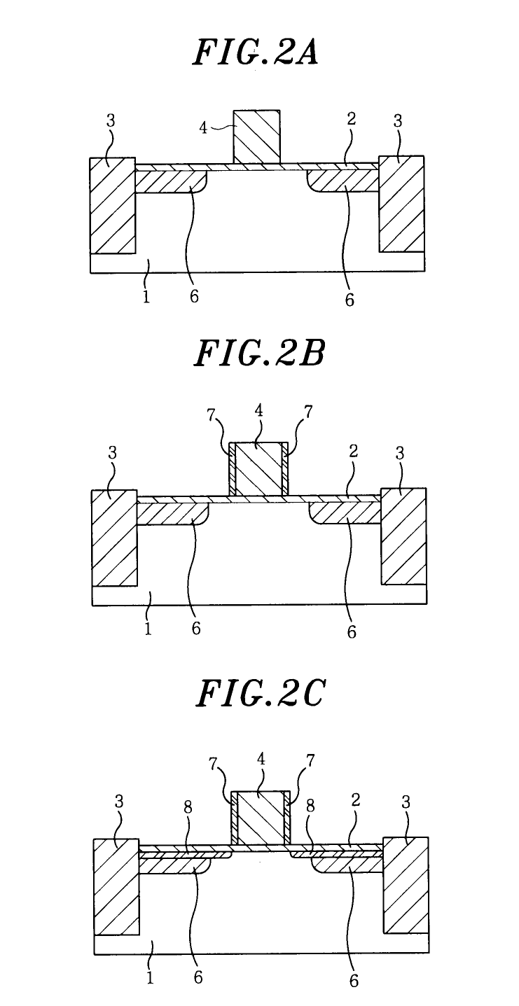

A first embodiment of the present invention will be explained with reference to FIGS. 1A to 1D and 2A to 2C.

In this embodiment, a GeCOH film is used as a mask for ion implantation.

First of all, as shown in FIG. 1A, a gate insulating film 2 made of silicon oxide is formed on a semiconductor substrate 1 made of, e.g., silicon, by using, e.g., a thermal oxidation method. Further, prior to the formation of the gate insulating film 2, a device isolation region 3 is formed on the semiconductor wafer 1 by using, e.g., a STI (Shallow Trench Isolation) technique.

Next, as illustrated in FIG. 1B, a gate electrode 4 is formed on the gate insulating film 2.

In the case of an nMOS transistor, the gate electrode 4 formed of a poly-Si film or a poly-SiGe film containing As or P as n-type impurities is formed. In the case of a pMOS transistor, the gate electrode 4 formed of a poly-Si film or a poly-SiGe film containing B as p-type impurities is formed (hereinafter, only one of the n-type or the p-type MOS transistor will be illustrated).

Further, the gate electrode 4 may be obtained by forming a poly-Si film of impurity-free and etching the poly-Si film by using a resist mask, and then n-type impurities or p-type impurities may be ion-implanted into the gate electrode 4 and the semiconductor substrate 1.

Next, as shown in FIG. 1C, the sidewall spacer film 5 is formed on the sidewall of the gate electrode 4. For example, a GeCOH film is formed on the semiconductor substrate 1 so as to coat the gate electrode 4, and then etched back to thereby form the sidewall spacer film (remaining portion) 5 on the sidewall of the gate electrode 4.

The GeCOH film is formed by a PECVD method using tetramethylgermanium (TMG) as a main source gas. As for an example of specific film forming conditions, the following conditions are applied to the film formation: a flow rate of TMG is about 200 sccm; a flow rate of CO₂ is about 200 sccm; a pressure in the chamber is about 267 Pa; a substrate temperature is about 300° C.; and a high frequency (RF) power of about 200 W having a frequency of about 13 MHz is applied to an upper electrode. As for a source gas of the GeCOH film, a gaseous mixture of GeH₄ and CH-based gas (e.g., CH₄ or the like) can be used other than the above-described TMG. Moreover, as for an apparatus for forming a GeCOH film, a CVD apparatus using a high-density plasma instead of PECVD can be used. Or, the film formation can be performed by using a PVD apparatus.

Next, as shown in FIG. 1D, a source•drain region 6 is formed by performing ion implantation while using as a mask the gate electrode 4 and the sidewall spacer film 5. In the case of an nMOS transistor, the source•drain region 6 is formed by ion-implanting n-type impurities. In the case of a pMOS transistor, the source•drain region 6 is formed by ion-implanting p-type impurities. Thereafter, in order to activate the source•drain region 6, heat treatment is performed at a high temperature of about 1000° C. by a spike RTA (Rapid Thermal Annealer).

Then, as illustrated in FIG. 2A, the sidewall spacer film 5 is removed by wet etching. The GeCOH film can be easily removed by an etching solution containing H₂SO₄ and H₂O₂. As for an etching solution, it is possible to use, other than the above etching solution, a solution containing NH₃OH and H₂O₂, a DHF (diluted hydrofluoric acid) solution, a hot phosphoric acid or the like. Further, the GeCOH film can also be removed by H₂O₂ depending on a composition thereof (ratio of each element).

Thereafter, as depicted in FIG. 2B, an SiN film is formed so as to cover the gate electrode 4, and then etched back to thereby form an offset spacer 7 on a sidewall of the gate electrode 4.

Next, as described in FIG. 2C, an extension region 8 is formed by ion-implanting n-type impurities or p-type impurities while using as a mask the gate electrode 4 and the offset spacer 7. In the case of an nMOS transistor, n-type impurities are ion-implanted, thereby forming an n-type extension region 8. In the case of the pMOS transistor, p-type impurities are ion-implanted, thereby forming a p-type extension region 8. Thereafter, in order to activate the extension region 8, heat treatment is carried out by using flash lamp annealing at a temperature lower than that for activating the source•drain region 6.

As described above, after completion of the formation of the source•drain region 6, the sidewall insulating film (sidewall spacer film 5) is removed and, then, the extension region 8 is formed. At this time, the sidewall insulating film is formed of a GeCOH film, so that the corresponding GeCOH film can be easily removed without leaving a residue and damaging a device structure section.

After a step for forming the extension region 8, a MOSFET forming process is continuously carried out by performing a step for forming an SiO₂ film so as to coat the gate electrode 4 and the offset spacer 7, a step for etching back the SiO₂ film to form a sidewall insulating film again. However, detailed description thereof will be omitted.

### Second Embodiment

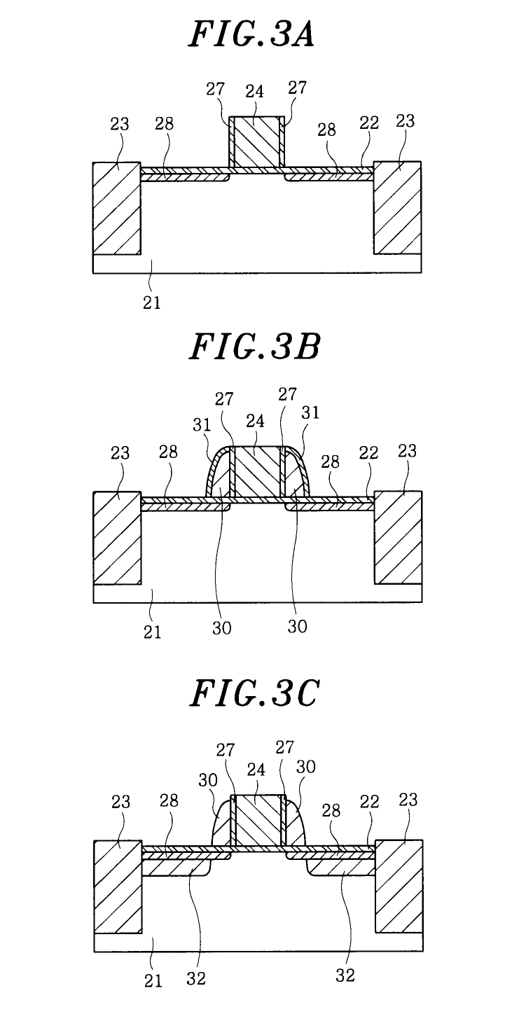

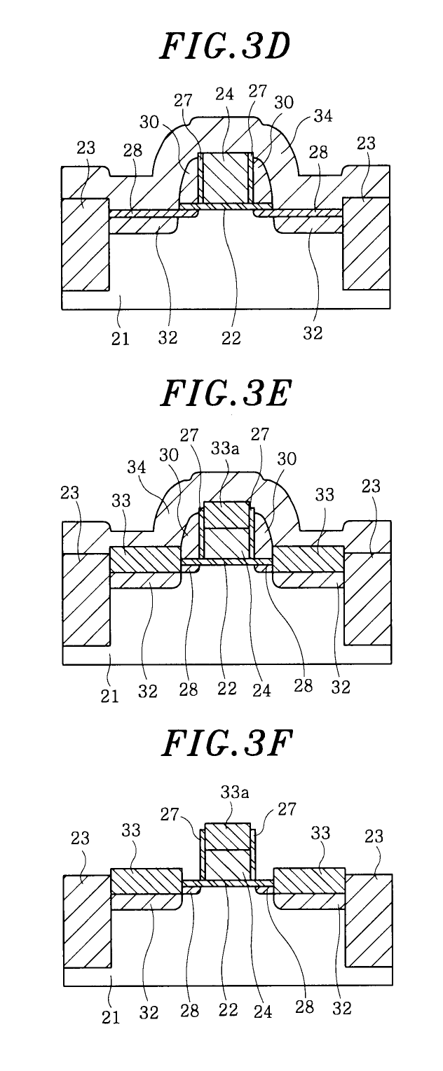

Hereinafter, a second embodiment of the present invention will be explained with reference to FIGS. 3A to 3F.

In this embodiment, first of all, a gate insulating film 22 (thickness of about 2 nm) is formed on a p-type (100) Si substrate 21 by thermal oxidation. Next, a poly-Si film (film thickness of about 150 nm) of impurity-free is formed by thermal CVD using a monosilane gas (SiH₄). An n-type MOS transistor forming region is coated by a lithography process, and boron (B) is ion-implanted into poly-Si of an uncoated p-type MOS transistor forming region under the conditions of an accelerated voltage of 2 kV and a dose amount of 5×10¹⁵ cm⁻². After a resist is peeled off by using oxygen plasma ashing, the p-type MOS transistor forming region is coated with a resist by another lithography process, and P (phosphorus) is ion-implanted into poly-Si of the n-type MOS transistor forming region with an accelerated voltage of about 15 kV and the dose amount same as that of B. Thereafter, the resist is peeled off by the oxygen plasma ashing, and residues are removed by using H₂O₂.H₂SO₄ mixed solution.

Next, a pattern corresponding to the gate electrode is formed by performing a lithography process, and a gate electrode 24 is formed by etching the poly-Si film while using a resist as a mask. After the poly-Si film had been etched, a peripheral portion of the gate electrode 24 is formed with a silicon oxide film 27 (SiO₂) by performing oxidation at a depth of about 2 nm under the oxygen atmosphere at about 800° C.

Thereafter, an extension portion 28 is formed by a lithography process again while using a resist as a mask. In the case of forming a p-type extension portion 28, ion implantation is performed with BF₃ (B:boron) under the conditions of an accelerated voltage of about 0.5 kV and a dose amount of about 7×10¹⁴ cm⁻². In the case of forming an n-type extension portion 28, As is ion-implanted under the conditions of an accelerated voltage of about 15 kV and a dose amount of about 7×10¹⁴ cm⁻².

FIG. 3A shows the state where the gate electrode 24 and the extension portion 28 are formed (hereinafter, only a single p-type MOS transistor will be illustrated).

Next, a GeCOH film is formed with a thickness of about 50 nm, and etched back by using a fluorocarbon gas. As a consequence, the GeCOH film is left on a sidewall of the gate electrode, thus forming a sidewall spacer film (remaining portion) 30.

The deposition conditions of the GeCOH film are the same as those of the first embodiment.

Next, an SiN film 31 having a thickness of about 10 nm is formed by plasma CVD using SiH₄ and NH₃ gas and etched back in the same manner by dry etching using a fluorocarbon gas. Accordingly, a sidewall spacer film of a two-layer structure is formed (FIG. 3B).

Thereafter, a resist is coated and, then, an n-type MOS transistor forming region is coated by a lithography process. A deep p⁺ region 32 is formed by implanting ions into a p-type MOS transistor forming region, and the resist is peeled off by oxygen plasma ashing. By repetitively performing the same processes, a deep n⁺ region is formed on the n-type MOS transistor forming region. Then, the resist is peeled off by the oxygen plasma ashing again.

Upon completion of the oxygen plasma ashing, residues generally remain and, also, metal contained in the resist remains on the substrate. In order to remove them, treatment using a H₂SO₄ and H₂O₂ mixed solution is generally performed. Since the GeCOH film is etched by the H₂SO₄ and H₂O₂ mixed solution, the sidewall spacer film 30 employs a laminated structure coated with the SiN film 31.

Then, the SiN film 31 is etched by using hot phosphoric acid. The SiN film 31 has a thin thickness of, e.g., about 10 nm, and thus can be easily removed (FIG. 3C).

Next, an Ni film 34 is deposited on the sidewall spacer film (remaining portion) 30 and the extension portion 28 disposed below a space formed by removing the GeCOH film. Namely, the substrate is loaded into a sputtering device, and the SiO₂ (gate insulating film 22) is sputter etched by using an Ar gas. Then, the Ni film 34 is formed by sputtering with a film thickness of 20 nm (FIG. 3D).

Thereafter, NiSi (nickel silicide) 33 is formed by reacting Ni and Si of the extension portion 28 exposed to the surface by performing heat treatment at about 450° C. for about 30 seconds (FIG. 3E). In this embodiment, the top surface of the gate electrode 24 is exposed, and came into contact with the Ni film 34. Therefore, NiSi (nickel silicide) 33a is formed on the top surface of the gate electrode 24.

Upon completion of the formation of the NiSi 33 and the NiSi 33a, the unreacted Ni film 34 is peeled off by using the H₂SO₄.H₂O₂ mixed solution. At this time, the GeCOH film (sidewall spacer film 30) is also removed. Due to this process, it is possible to obtain a state where the sidewall spacer film 30 has been removed without damaging the NiSi 33 and the NiSi 33a, as illustrated in FIG. 3F.

### Third Embodiment

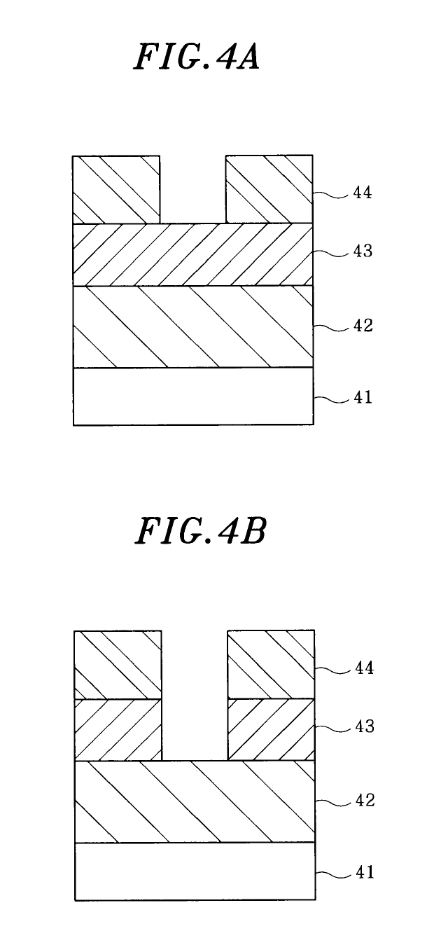

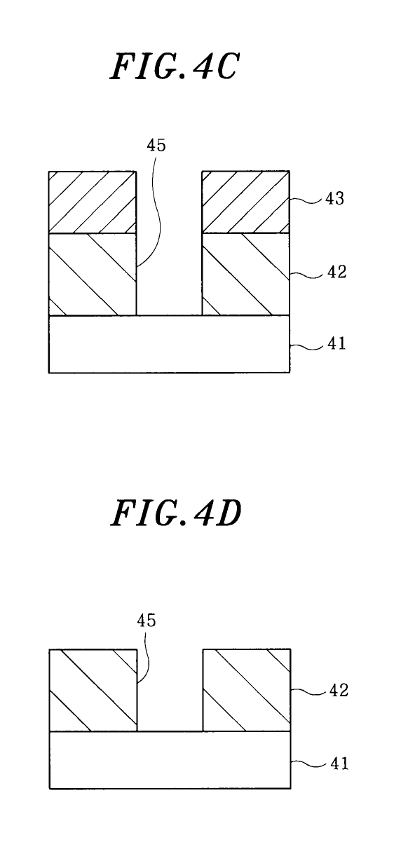

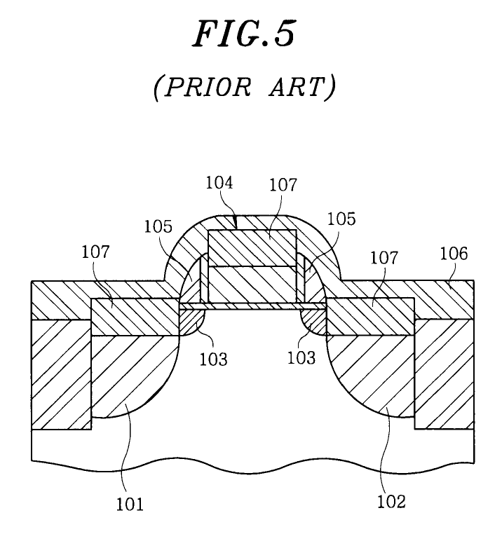

Hereinafter, a third embodiment in which an interlayer dielectric is etched by using a GeCOH film as a mask_will be explained with reference to FIGS. 4A to 4D.

As depicted in FIG. 4A, a GeCOH film 43 as a mask film is formed so as to coat the interlayer dielectric 42 formed on the silicon semiconductor substrate 41. Further, a resist film 44 having a predetermined opening is formed on the mask film 43 by a photolithography process. In this embodiment, a substrate to be processed includes a silicon semiconductor substrate 41 and an interlayer dielectric 42 formed on the silicon semiconductor substrate 41.

In the plasma etching using Cl₂ gas or CF-based gas, the GeCOH film has a sufficient etching selectivity to the resist film 44. Further, as shown in FIG. 4B, the opening pattern of the resist film 44 is transferred to the GeCOH film by plasma etching using the above gases, thereby forming a GeCOH film (remaining portion) 43 that is partially opened.

Next, as shown in FIG. 4C, after the resist film 44 had been removed, an opening 45 such as a trench groove or a via hole for wiring is formed by etching the interlayer dielectric 42 formed below the GeCOH film 43 while using as a mask the GeCOH film 43 to which the opening pattern had been transferred. In the plasma etching using a CF-base gas, SiO₂ or SiN used for the interlayer dielectric 42 has a sufficient etching selectivity to the GeCOH film 43, thus the GeCOH film 43 serves as a mask.

Thereafter, as illustrated in FIG. 4D, the GeCOH film is removed by wet etching using solution containing H₂SO₄ and H₂O₂. In this wet etching, unlike in the plasma etching using a CF-based gas, the etching rate of the GeCOH film 43 is sufficiently higher than that of the interlayer dielectric 42. Therefore, the GeCOH film 43 can be removed without damaging the interlayer dielectric 42.

Although the embodiments of the present invention have been described, the present invention is not limited to the above-described embodiments. For example, in a strained silicon technique for increasing mobility of a carrier in a channel by straining silicon crystals, an epitaxial growth of silicon germanium is performed on a source and drain, and a silicon nitride film for applying compressive stress to a gate is coated thereon, thereby applying compressive stress to a p-type MOS transistor. At this time, a GeCOH film may be used as a cap material for preventing the growth of the silicon germanium on the gate. In this case as well, the removal can be easily carried out by wet etching without damaging the gate.

Besides, although a GeCOH film is used in the above embodiments, a GeCH film can also be used.

What is claimed is:

1. A method for manufacturing a semiconductor device comprising:
a step of forming a first thin film composed of GeCOH or GeCH on a substrate to be processed;
a step of removing a portion of the first thin film to obtain a sidewall spacer film of MOS transistor; and
a processing step of performing a process on the substrate through a space from which the first thin film is removed.

2. The method for manufacturing the semiconductor device of claim 1, wherein the processing step includes a step of implanting ions of an element into the substrate through the space formed by removing the portion.

3. The method for manufacturing the semiconductor device of claim, 1, further comprising a step of removing the sidewall spacer film and a step of implanting ions of an element into the substrate through a space formed by removing the sidewall spacer film.

4. The method for manufacturing the semiconductor device of claim 1, further comprising a step of depositing a second thin film on the substrate disposed below the space formed by removing the portion of the first thin film, wherein the processing step includes a step of forming a third thin film by chemically reacting the substrate and the second thin film in the space.

5. The method for manufacturing the semiconductor device of claim 4, wherein the sidewall spacer film and the second thin film are removed while leaving the third thin film.

6. The method for manufacturing the semiconductor device of claim 1, further comprising:
a step of removing the sidewall spacer film,
wherein the step of removing the portion of the first thin film to obtain the sidewall spacer film of MOS transistor, or the step of removing the sidewall spacer film is performed by using a wet etching method.

7. The method for manufacturing the semiconductor device of claim 6, wherein the wet etching method is carried out by using etching solution containing H₂SO₄ and H₂O₂.

8. (canceled)

9. (canceled)

10. A semiconductor device manufactured by a manufacturing method comprising a step of forming a first thin film composed of GeCOH or GeCH on a substrate to be processed; a step of removing a portion of the first thin film to obtain a sidewall spacer film of MOS transistor; and a processing step of performing a certain process on the substrate through a space formed by removing the portion of the first thin film.
